(19) United States
(12) Patent Application Publication
(10) Pub. No.: US 2010/0263207 A1
(43) Pub. Date: Oct. 21, 2010

(54) Panelizing Method for Printed Circuit Board Manufacturing

(76) Inventor: Kimmo Paananen, Salo (FI)

Correspondence Address: MARSHALL, GERSTEIN & BORUN LLP, 233 SOUTH WACKER DRIVE, 6300 WILLIS TOWER, CHICAGO, IL, 60606-6357, US

(21) Appl. No.: 12/743,843

(22) PCT Filed: Nov. 25, 2008
(86) PCT No.: PCT/FI08/50682

§ 371 Date: May 20, 2010

(30) Foreign Application Priority Data
Nov. 27, 2007 (FI) 20070910

(51) Int. Cl. H05K 3/36

(52) U.S. Cl. 29/829

(57) ABSTRACT

The invention relates to a method for connecting at least two printed circuit board modules to form a printed circuit board panel by means of a virtual panel. The method for connecting printed circuit board modules uses positioning tags and counterparts thereof, which align the printed circuit board modules to a target location on the printed circuit board panel.

### BACKGROUND OF THE INVENTION

The invention relates to a method for connecting printed circuit board modules, in which method at least two printed circuit board modules are connected to form a printed circuit board panel by means of a virtual panel.

Currently, it is very common to use printed circuit boards in the manufacture of electronic products. One printed circuit board may consist of one or more printed circuit board blanks, i.e. modules.

It is slow and cumbersome both for the printed circuit board manufacturer and for the electronics manufacturer to process individual circuit board modules. There is a general tendency to increase manufacturing capacity by combining a plurality of printed circuit board modules into one whole, a so-called printed circuit board panel. In that case the printed circuit board manufacturer pre-cuts the modules, but leaves material between the modules, so-called material necks, to connect the modules. The whole connected by these material necks is thus called a printed circuit board panel.

As smaller and smaller, and more complicated electronic devices are to be achieved, the packing density of electronic components has increased. This makes it difficult to manufacture printed circuit boards, whereby one or more modules in a printed circuit board panel may be damaged or dimensional variations of the printed circuit board material in the panel between the surface copper layers of the modules may be excessively large. Typically, panels of this kind have been rejected, which causes great material waste, because in that case functioning modules must be rejected as well. Faults in printed circuit board modules thus considerably reduce the capacity and yield of mass production of electronic printed circuit boards.

Yield of mass production in electronics is reduced, for instance, by the fact that the paste printing process becomes more difficult, because a paste printing stencil is typically positioned with the assistance of alignment marks on the panel. The location of an individual module in the panel may differ, however, from what is assumed. A so-called reflow furnacing, which belongs to the SMD (Surface Mounted Device) process, also increases dimensional variations in the printed circuit board panel. The effect of the re-flow process is significant, when high-precision components are stacked on the other side of the panel. Because of the dimensional requirements the SMD process sets for the circuit board panel, the optimal size of the panel has to be reduced. Consequently, the capacity of electronic production reduces, because the number of modules on the panel decreases.

### BRIEF DESCRIPTION OF THE INVENTION

It is the object of the present invention to provide a novel and improved panelizing method for printed circuit board manufacturing.

The method of the invention is characterized by interconnecting the printed circuit board modules using positioning tags and counterparts thereof, the positioning tags and the counterparts being formed such that they align the modules to a target location on a printed circuit board panel.

The basic idea of the invention is that the printed circuit board modules may be interconnected by using positioning tags and counterparts thereof that are precisely matched to one another, by means of which the printed circuit board modules may be positioned precisely with respect to one another and the printed circuit board panel. By measuring the positioning tag and/or the counterpart thereof with the assistance of machine vision, accurate information on their shape and centre of shape will be obtained, and this information is employed for forming an auxiliary data file used as a so-called virtual panel. As the modules in the printed circuit board panel may be selected freely, the assembly of a printed circuit board panel may only employ printed circuit board modules that are found both electrically functioning and having dimensions within a tolerance range.

The invention has an advantage that thereby it possible to improve dimensional precision in surface copper layers of a printed circuit board panel between the printed circuit board modules and to reduce dimensional variations between the panels, to enable removal of damaged printed circuit board modules from the production panel and to increase the number of modules in the panel. With these improvements it possible to increase significantly the capacity and yield of printed circuit board manufacturing and electronic production as compared with the prior art methods. The method allows minimization of process steps required for connection and enables simple manufacture of process automation. This is particularly advantageous from the viewpoint of mass production, where the relation between the investment costs and the capacity is of importance.

The basic idea of an embodiment of the invention is to measure the shape of at least a positioning tag or a counterpart thereof by means of machine vision.

The basic idea of a second embodiment of the invention is to measure the centre point of at least a positioning tag or a counterpart thereof by means of machine vision.

The basic idea of a third embodiment of the invention is to use for determining the centre point of the positioning tag or the counterpart thereof a reference point that will appear in the same frame of a machine vision camera with the positioning tag or the counterpart thereof.

The basic idea of a fourth embodiment of the invention is that each end of each printed circuit board module is connected to a printed circuit board panel with at least two positioning tags.

The basic idea of a fifth embodiment of the invention is that each end of each printed circuit board module is connected to a printed circuit board panel with one positioning tag.

The basic idea of a sixth embodiment of the invention is to form neck parts to be used in connecting the printed circuit board modules or to make separate positioning tags of a material other than the printed circuit board.

### BRIEF DESCRIPTION OF THE DRAWINGS

Some embodiments of the invention are described in greater detail in the attached drawings, in which

FIG. 1 shows schematically a printed circuit board panel,

FIG. 2 shows schematically a detail of the connection of the printed circuit board modules of FIG. 1,

FIG. 3 shows schematically a detail of a second connection of printed circuit board modules,

FIG. 4 shows schematically a detail of a third connection of printed circuit board modules.

For the sake of clarity, some embodiments of the invention are shown in a simplified manner in the figures. Like reference numerals refer to like parts in the figures.

### DETAILED DESCRIPTION OF THE INVENTION

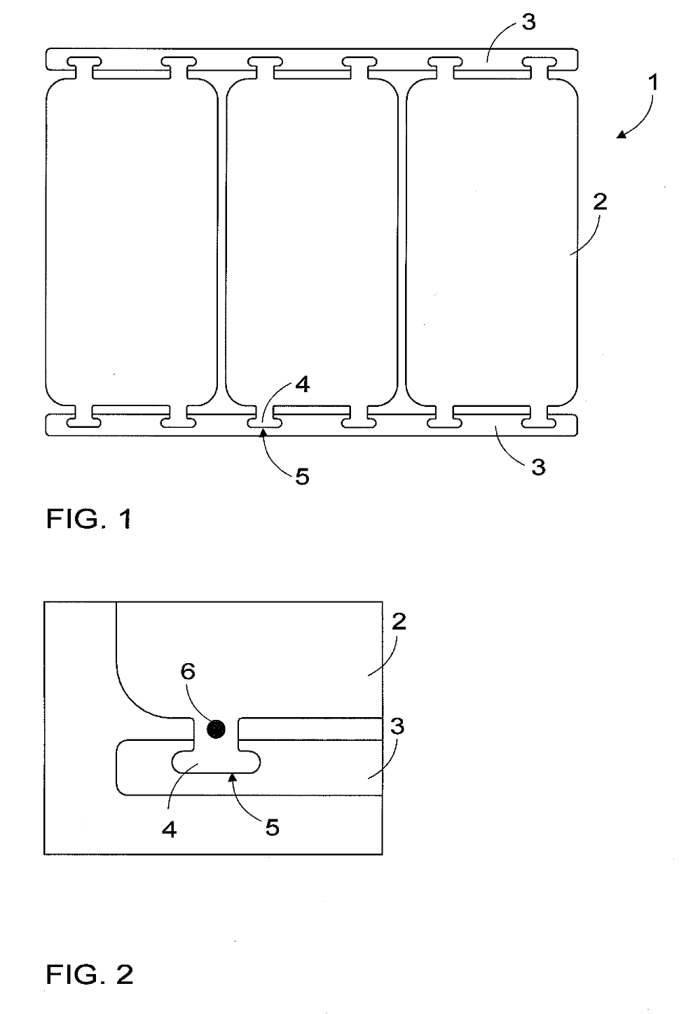

FIG. 1 shows a printed circuit board panel 1. The printed circuit board panel 1 comprises two or more printed circuit board modules 2. FIG. 1 depicts three printed circuit board modules 2. As individual printed circuit board modules 2 are connected to form a printed circuit board panel, the modules may be selected from modules that are already found electrically and dimensionally functioning, which improves the capacity and yield of the production. In the embodiment of FIG. 1, the printed circuit board modules 2 are connected by two so-called neck parts 3. Each printed circuit board module 2 is connected to the neck part 3 with clearance-free shape-locking, which consists of one or more positioning tags 4 and counterparts 5 of each positioning tag. FIGS. 2 to 4 show alternative ways of forming this clearance-free shape-locking.

FIG. 2 shows a detail of the printed circuit board panel 1 of FIG. 1. For connecting to the printed circuit board panel 1, the printed circuit board module 2 is provided with a positioning tag 4 that is machined, for instance. The shape of the positioning tag 4 may vary a great deal as compared with what is shown in FIG. 2, if only the shape of the positioning tag 4 allows formation of clearance-free shape-locking, by which printed circuit board modules 2 are combined into a printed circuit board panel 1. There may be for instance two positioning tags for each end of the printed circuit board modules 2, i.e. four tags in total per module 2, as appears in FIG. 1, or more but in a connection of this kind dimensional variation of parts within a tolerance range may cause stresses in the printed circuit board module 2 connected to the printed circuit board panel 1. These torsional forces may be minimized by using one large positioning tag 4, instead of two or more positioning tags 4, for each end of the printed circuit board module 2.

FIG. 2 further shows a reference point 6 in a surface copper layer of the end of the printed circuit board module 2. The reference point 6 may be a point that is particularly provided for positioning, a so-called copper pad intended for connecting an SMD component or another point suitable for positioning and locating in an appropriate area in the vicinity of the positioning tag, irrespective of the actual purpose of use. Selection and disposition of the reference point 6 is only restricted by the fact that the reference point 6 should appear in the same frame of a machine vision camera as the positioning tag 4.

The shape and the centre point of the positioning tag 4 of the printed circuit board 2 in relation to the reference point 6 of the end of the printed circuit board module 2 is measured by means of machine vision. The machine vision refers to a system which typically comprises at least a camera, a computer and a computer-run image processing program that interprets the camera frame for data automatically. Firstly, in this case there is determined the x and y coordinates of the centre point of a positioning tag in relation to an adjacent reference point 6 and by means of these data there is formed a so-called connection point coordinate system. In addition, the shape of the positioning tag 4 is stored in memory for the machining of the counterpart 5. In some embodiments, instead of the centre point of the positioning tag 4, it is possible to use directly the shape of the edge line of the positioning tag 4 for the determination of a distance between the positioning tag 4 and the reference point 6. In addition to those mentioned above, it is also possible to carry out other measurements or determinations at the same time. Preferably, it is possible to use a high-resolution camera depending on the requirements for dimensional precision, because the best attainable dimensional precision depends on the resolution of the camera employed and on the size of the selected image field. In that case the image field may be, for instance, 12*9 mm and the camera resolution at least 6 megapixels correspondingly. The selection of the image field and the reference point is performed such that the positioning tag 4 and the reference point 6 are to fit in the frame simultaneously.

The distances between the reference points 6 of the printed circuit board module 2 are measured and a so-called module coordinate system is provided therefrom. Measurement is performed using at least one camera, but in different embodiments there may also be two or more cameras. The measurement of the reference points 6 enables determination of a centre of mass of the module 2, for instance, which may be used in determination of a so-called virtual panel.

The virtual panel represents the best possible whole that may be provided from the measured printed circuit board modules 2 in relation to the targeted printed circuit board panel in accordance with the drawing. In addition to the determination of the module coordinate system and the connection point coordinate system of the virtual panel, machine vision cameras may be preferably used for measuring an offset between the surface copper layers of the opposite sides of the printed circuit board module 2. In that case the location of the reference point 6 in comparison with the positioning tag 4, more precisely with its centre point or the shape of its edge line, is determined separately on both sides of the printed circuit board module 2. This may be performed by measuring the printed circuit board module 2 on both sides alternately with the same camera or the same cameras, or by arranging the cameras or a plurality of cameras on both sides of the printed circuit board module 2, whereby the measurement may be carried out on both sides simultaneously. Particularly preferably the determination employs the same camera or the same cameras as the determination of the module coordinate system and the connection point coordinate system, and still more preferably the determinations may be performed simultaneously. The offset, i.e. the mutual transfer between upper and lower copper surfaces of the module 2 should be equal in size and in the same direction in each module 2 of the panel 1, in order for both sides of the printed circuit board panel 1 to remain within the tolerance range. Hence, the measurement of the offset is of great importance to the formation of the final, dimensionally precise panel.

The result of the virtual panel calculation is used as machining path data for the counterpart 5. The virtual panel may be formed in a variety of ways by utilizing various calculation models, whereby the objective is to create from the measured modules 2 a whole that corresponds in the best possible manner to the target panel in accordance with the drawing. This may be implemented, for instance, by using in combination the module and the connection point coordinate systems, the offset information on the surface copper layers of the modules 2 and the shape information on the positioning tags 4.

As the virtual panel is formed, the module coordinate system may be rotated in plane, for instance, about the centre of mass, until the distance of each reference point 6 from the corresponding point in the drawing is equal. If the other side of the measured, actual module 2 is not identical, the coordinates of the centres of mass of the modules and the rotation of the module may be necessary to optimize. It may also be necessary to reject a module 2 from the panel, if it is impossible for the reference points 6 to remain within tolerance values, despite the rotation of the module. Typically, the printed circuit board module 2 must be rejected, because the offset in the surface copper layers of its opposite sides is excessive.

Neck parts 3 connecting the printed circuit board modules 2 are machined on the basis of the virtual panel data to correspond to the shape data of each positioning tag 4 of each printed circuit board module 2 such that the centre point of each counterpart 5 is determined on the basis of the x and y coordinates of the centre point of the respective positioning tag 4. In that case there is a dedicated counterpart 5 in the neck part for each positioning tag 4 and by means of these positioning tags 4 and counterparts 5 the printed circuit board modules 2 are aligned and positioned in the printed circuit board panel to implement the best possible panel.

The printed circuit board modules 2 are typically conveyed by a circuit board conveyor first to a machine vision station for measurements and virtual panel formation. The measured printed circuit board modules 2 may be preferably placed in a short-term intermediate storage, which serves as a so-called module library and wherefrom the most suitable printed circuit board modules 2 may be selected to form the best possible printed circuit board panel 1. Thereafter, the printed circuit board modules 2 are transferred to an assembly station, where the printed circuit board modules 2 and the neck parts 3 are aligned and pressed against one another, whereby the positioning tags 4 and the counterparts 5 align the printed circuit board modules 2 to the target location in the printed circuit board panel 1. Connection of the parts employs clearance-free shape-locking. Between the shape-locking it is possible to use an adhesive agent, if so desired, and/or to apply lacquer on the connection, but this is not necessary. Once the printed circuit board modules 2 are completed, the shape-locking may be detached by pressing and the positioning tags 4 are removed from the printed circuit board module 2 by milling, for instance.

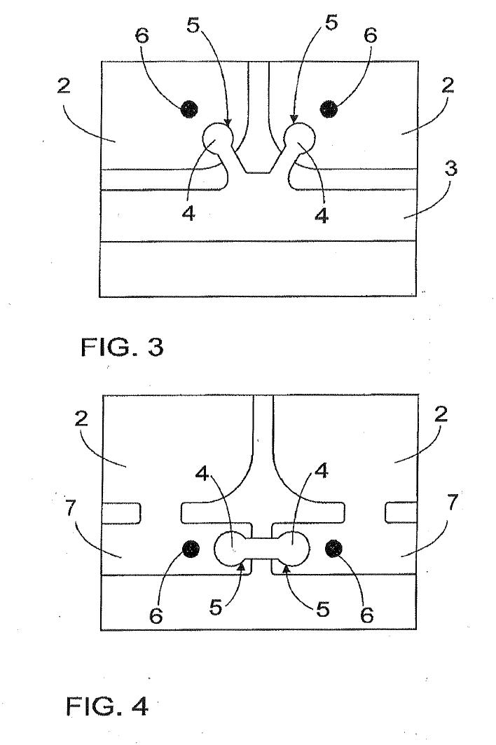

FIG. 3 shows an embodiment, in which the positioning tags 4 are arranged in the neck part 3 and the counterparts 5 and the reference points 6 are arranged in the printed circuit board module 2. In this embodiment the determination of a virtual panel and the manufacturing and assembly of the parts takes place in a completely corresponding manner as what is described above, but, instead of the shape and centre point of the positioning tag 4, the printed circuit board module 2 is determined for the shape and centre point of the counterpart 5, and the coordinate system is formed and the positioning tags 4 of the neck part 3 are machined on the basis of this data. Once the shape-locking joints of the finished printed circuit board module 2 have been detached, the printed circuit board module 2 need not be machined in this embodiment, because it does not include positioning tags to be removed. So-called depanelization of this kind is particularly advantageous from the view-point of the manufacturing process, because detachment by pressing is dust-free, fast and economical.

FIG. 4 shows an embodiment, in which a separate neck part 3 connecting the printed circuit board modules 2 is not employed. Instead, each printed circuit board module is provided with an end part 7. In the end part 7, in turn, there is machined a counterpart 5 and arranged a reference point 6. In this case the positioning tag 4 used for connecting the printed circuit board modules 2 is a separate piece, in which there are machined shapes corresponding to the counterparts 5 of two adjacent printed circuit board modules 2. Once the printed circuit board panel is finished, the end parts 7 are detached from the printed circuit board module 2 by milling, for instance. Otherwise the determination of the virtual panel, manufacturing and assembly of the parts take place in the same manner as what is described in connection with FIG. 2.

The method disclosed in this application allows dimensional precision of a surface copper layer in a printed circuit board panel 1 to be improved between the adjacent modules and in relation to the alignment marks in the printed circuit board panel. Yield of the manufacturing process may be improved by forming the printed circuit board panels only of the printed circuit board modules that have been found functioning. In the neck part 3 connecting the modules or in separate positioning tags 4 it is further possible to use material other than that of the printed circuit board. Preferably, this may be material, for instance metal, which when cooling down to the operating temperature, restores its shape better than the circuit board material, whereby the dimensional precision of the printed circuit board panel after the reflow furnacing of the SMD process may be further improved. In the neck part 3 connecting the modules or in the separate positioning tags 4 it is also possible to use less expensive material, for instance FR2, than circuit board material, typically FR4.

In some cases the features disclosed in this application may be used as such, irrespective of other features. On the other hand, the features disclosed in this application may be combined, when necessary, to provide various combinations.

The drawings and the relating description are only intended to illustrate the inventive idea. The details of the invention may vary within the scope of the claims.

1. A method for connecting printed circuit board modules, in which method at least two printed circuit board modules are connected to form a printed circuit board panel by means of a virtual panel, by connecting the printed circuit board modules to form the printed circuit board panel using positioning tags and counterparts thereof, the positioning tags and the counterparts being formed such that they align and connect the modules to a target location on the printed circuit board panel.

2. The method of claim 1, wherein at least the shape of the positioning tag or the counterpart thereof is measured by means of machine vision.

3. The method of claim 1, wherein at least the centre point of the positioning tag or the counterpart thereof is measured by means of machine vision.

4. The method of claim 2, wherein using in the determination of the centre point or the edge line shape of the positioning tag or the counterpart thereof is used a reference point that will fit in the same machine vision camera frame with the positioning tag or the counterpart thereof.

5. The method of claim 3, wherein in the determination of the centre point or the edge line shape of the positioning tag or the counterpart thereof is used a reference point that will fit in the same machine vision camera frame with the positioning tag or the counterpart thereof.

6. The method of claim 1, wherein the printed circuit board modules are connected to form the printed circuit board panel with at least two positioning tags at each end of each printed circuit board module.

7. The method of claim 1, wherein the printed circuit board modules are connected to form the printed circuit board panel with one positioning tag at each end of each printed circuit board module.

8. The method of claim 1, wherein the printed circuit board modules are interconnected to form the printed circuit board panel using positioning tags and counterparts thereof, the positioning tags and the counterparts being formed such that they align and connect the modules with shape-locking to a target location on the printed circuit board panel.

9. The method of claim 1, wherein the printed circuit board modules are connected by neck parts to form the printed circuit board panel using positioning tags and counterparts thereof, the positioning tags and the counterparts being formed such that they align and connect the modules with shape-locking to a target location on the printed circuit board panel.

10. The method of claim 1, wherein the neck parts or separate positioning tags used in connecting the printed circuit board modules are formed of a material other than that of the printed circuit board modules.

11. The method of claim 10, wherein the neck parts or separate positioning tags used in connecting the printed circuit board modules are formed of a material, for instance metal, which when cooling down to the operating temperature restores its shape better than the circuit board material.

12. The method of claim 10, wherein the neck parts or the separate positioning tags, used in connecting the printed circuit board modules, are formed of a less expensive material, such as FR2, than the printed circuit board material.
